(19) United States
(12) Patent Application Publication
(10) Pub. No.: US 2022/0371533 A1
(43) Pub. Date: Nov. 24, 2022

(54) DISTRIBUTED VEHICLE BODY SENSORS FOR EVENT DETECTION

(71) Applicant: Motional AD LLC, Boston, MA (US)

(72) Inventors: Ruben Strenzke, Singapore (SG); Aravindkumar Vijayalingam, Singapore (SG); Alejandro Israel Barragan Diaz, Singapore (SG)

(21) Appl. No.: 17/324,022

(22) Filed: May 18, 2021

(51) Int. Cl. B60R 21/013; B60W 40/12; B60W 50/14; B60W 60/00

(52) U.S. Cl. CPC B60R 21/013; B60W 40/12; B60W 50/14; B60W 60/001; B60W 2420/54; B60W 2420/10; B60R 2021/01302; B60R 2021/0002

(57) ABSTRACT

Systems and techniques are described for event detection. A described system includes a vehicle body containing body regions, sensors, processor, and memory. The sensors can include at least one sensor positioned about at least one body region of the body regions. The at least one body region can be associated with a region event type. The memory can store instructions thereon that, when executed by the processor, cause the processor to perform operations which can include obtaining data associated with at least one sensor measurement from the at least one sensor, determining that the at least one sensor measurement is associated with the region event type, and determining that an event associated with the region event type occurred based on determining that the at least one sensor measurement is associated with the region event type and that the at least one body region is associated with the region event type.

### FIELD OF THE INVENTION

This description relates to vehicle based sensor systems.

### BACKGROUND

Vehicles can be equipped with sensors such as cameras, radar, LiDAR (Light Detection and Ranging), accelerometers, and micro-electro-mechanical systems (MEMS) gyroscope (MEMS gyro). Other types of sensors are possible. A vehicle can use sensor input to manage and control the vehicle.

### BRIEF DESCRIPTION OF THE DRAWINGS

FIG. 1 shows an example of an autonomous vehicle having autonomous capability.

FIG. 2 shows a computer system.

FIG. 3 shows an example architecture for an autonomous vehicle.

FIG. 4 shows an example of inputs and outputs that can be used by a perception module.

FIG. 5 shows an example of sensors distributed about body regions of a vehicle.

FIG. 6 shows an example of an architecture of a distributed sensor system.

FIG. 7 shows a diagram of an example of sensor configurations within a body region of a vehicle.

FIG. 8 shows a diagram of an example of audio sensors within a body region of a vehicle.

FIG. 9 shows a diagram of an example of sensors within a door region of a vehicle.

FIG. 10 shows a flowchart of an example of a process that performs event detection.

### DETAILED DESCRIPTION

In the following description, for the purposes of explanation, numerous specific details are set forth in order to provide a thorough understanding of the present invention. It will be apparent, however, that the present inventions may be practiced without these specific details. In other instances, well-known structures and devices are shown in block diagram form in order to avoid unnecessarily obscuring the present invention.

In the drawings, specific arrangements or orderings of schematic elements, such as those representing devices, modules, instruction blocks and data elements, are shown for ease of description. However, it should be understood by those skilled in the art that the specific ordering or arrangement of the schematic elements in the drawings is not meant to imply that a particular order or sequence of processing, or separation of processes, is required. Further, the inclusion of a schematic element in a drawing is not meant to imply that such element is required in all embodiments or that the features represented by such element may not be included in or combined with other elements in some embodiments.

Further, in the drawings, where connecting elements, such as solid or dashed lines or arrows, are used to illustrate a connection, relationship, or association between or among two or more other schematic elements, the absence of any such connecting elements is not meant to imply that no connection, relationship, or association can exist. In other words, some connections, relationships, or associations between elements are not shown in the drawings so as not to obscure the disclosure. In addition, for ease of illustration, a single connecting element is used to represent multiple connections, relationships or associations between elements. For example, where a connecting element represents a communication of signals, data, or instructions, it should be understood by those skilled in the art that such element represents one or multiple signal paths (e.g., a bus), as may be needed, to affect the communication.

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

Several features are described hereafter that can each be used independently of one another or with any combination of other features. However, any individual feature may not address any of the problems discussed above or might only address one of the problems discussed above. Some of the problems discussed above might not be fully addressed by any of the features described herein. Although headings are provided, information related to a particular heading, but not found in the section having that heading, may also be found elsewhere in this description. Embodiments are described herein according to the following outline:
1. General Overview
2. System Overview
3. Autonomous Vehicle Architecture
4. Autonomous Vehicle Inputs
5. Event Detection Mechanisms

### General Overview

The inventions are directed to sensor systems and sensor data processing techniques that detect events such as events corresponding to low-severity collisions which can be referred to as contact events. These contact events can be further divided into various body regions of a vehicle. For example, a contact event originating from the passenger-side body region can be deemed a passenger-side event or a passenger-side contact event.

Vehicles typically have sensors and systems to detect and respond to high-severity collisions (e.g., ones that require air bag deployment or trigger a call to a monitoring center). However, in many jurisdictions, all collisions of a car, including low-severity ones, have to be detected by the human driver, and the driver is required to stop the car, assess damage and injuries, and report these if necessary. With the sensors currently deployed on modern cars and AVs, it is not possible to reliably detect collisions with an object or (infra)structure element at low relative velocities or a light object or (infra)structure element (e.g., cat or small dog).

These inventions use distributed sensors in various body regions around the vehicle—attached to the interior or exterior side of a vehicle's body region—to detect collisions that either deform or do not deform the vehicle's body part. Data from these sensors can be fused by computer software during AV operations to detect collisions, e.g., a low-severity collisions, that may be missed by the AV's main collision detection mechanisms. If a single body region or multiple neighboring body regions are affected by the specific mechanical shock, vibration, or noise, then a (low-severity) collision is likely to have taken place. In some embodiments, a mechanical shock, vibration, or noise that is sensed as a similar pattern by sensors related to multiple body regions can be filtered, e.g., excluded, by the software, in that case shifting the responsibility of detecting a severe collision to the main collision detection mechanisms.

The techniques and systems described herein can detect collisions including low-severity collisions. The techniques and systems can differentiate between high-severity and low-severity collisions. The techniques and systems can detect low-severity collision that may be missed by high-severity detection mechanisms. The techniques and systems can alert a driver to low-severity collision including low-impact collisions with small or large objects that under some jurisdictions require the driver to stop the car and assess any potential damages, injuries, or both. The techniques and systems can alert an automated driving system of a low-severity collision. The techniques and systems can be implemented using low-cost sensors. In addition to vehicles, the techniques and systems can be implemented in off-road, water, underwater, or aerial vehicles. Such vehicles can be tele-operated, autonomously operated, manually operated, or a combination thereof.

### System Overview

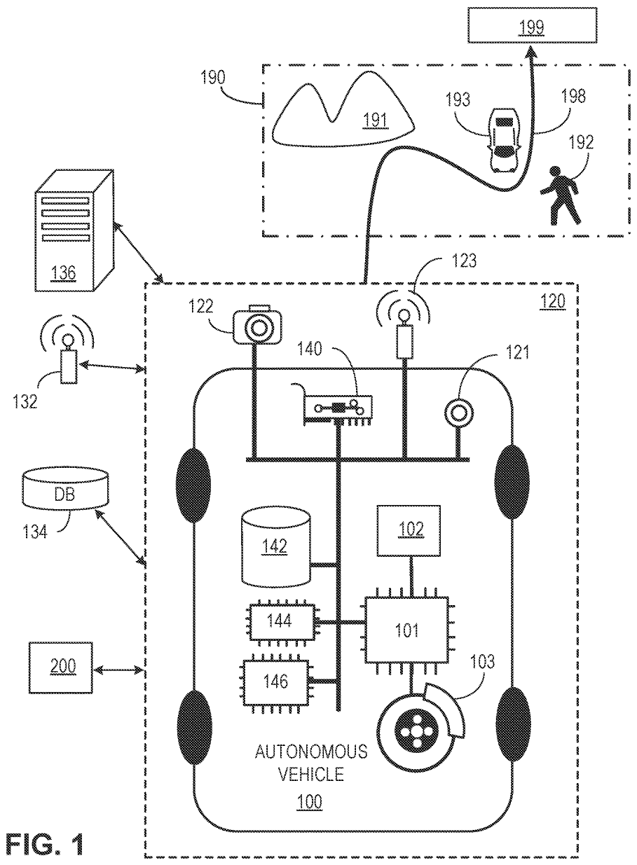

FIG. 1 shows an example of an autonomous vehicle 100 having autonomous capability.

As used herein, the term “autonomous capability” refers to a function, feature, or facility that enables a vehicle to be partially or fully operated without real-time human intervention, including without limitation fully autonomous vehicles, highly autonomous vehicles, and conditionally autonomous vehicles.

As used herein, an autonomous vehicle (AV) is a vehicle that possesses autonomous capability.

As used herein, “vehicle” includes means of transportation of goods or people. For example, cars, buses, trains, airplanes, drones, trucks, boats, ships, submersibles, dirigibles, etc. A driverless car is an example of a vehicle.

As used herein, “trajectory” refers to a path or route to navigate an AV from a first spatiotemporal location to second spatiotemporal location. In an embodiment, the first spatiotemporal location is referred to as the initial or starting location and the second spatiotemporal location is referred to as the destination, final location, goal, goal position, or goal location. In some examples, a trajectory is made up of one or more segments (e.g., sections of road) and each segment is made up of one or more blocks (e.g., portions of a lane or intersection). In an embodiment, the spatiotemporal locations correspond to real world locations. For example, the spatiotemporal locations are pick up or drop-off locations to pick up or drop-off persons or goods.

As used herein, “sensor(s)” includes one or more hardware components that detect information about the environment surrounding the sensor. Some of the hardware components can include sensing components (e.g., image sensors, biometric sensors), transmitting and/or receiving components (e.g., laser or radio frequency wave transmitters and receivers), electronic components such as analog-to-digital converters, a data storage device (such as a RAM and/or a nonvolatile storage), software or firmware components and data processing components such as an ASIC (application-specific integrated circuit), a microprocessor and/or a microcontroller.

As used herein, a “scene description” is a data structure (e.g., list) or data stream that includes one or more classified or labeled objects detected by one or more sensors on the AV vehicle or provided by a source external to the AV.

As used herein, a “road” is a physical area that can be traversed by a vehicle, and may correspond to a named thoroughfare (e.g., city street, interstate freeway, etc.) or may correspond to an unnamed thoroughfare (e.g., a driveway in a house or office building, a section of a parking lot, a section of a vacant lot, a dirt path in a rural area, etc.). Because some vehicles (e.g., 4-wheel-drive pickup trucks, sport utility vehicles, etc.) are capable of traversing a variety of physical areas not specifically adapted for vehicle travel, a “road” may be a physical area not formally defined as a thoroughfare by any municipality or other governmental or administrative body.

As used herein, a “lane” is a portion of a road that can be traversed by a vehicle. A lane is sometimes identified based on lane markings. For example, a lane may correspond to most or all of the space between lane markings, or may correspond to only some (e.g., less than 50%) of the space between lane markings. For example, a road having lane markings spaced far apart might accommodate two or more vehicles between the markings, such that one vehicle can pass the other without traversing the lane markings, and thus could be interpreted as having a lane narrower than the space between the lane markings, or having two lanes between the lane markings. A lane could also be interpreted in the absence of lane markings. For example, a lane may be defined based on physical features of an environment, e.g., rocks and trees along a thoroughfare in a rural area or, e.g., natural obstructions to be avoided in an undeveloped area. A lane could also be interpreted independent of lane markings or physical features. For example, a lane could be interpreted based on an arbitrary path free of obstructions in an area that otherwise lacks features that would be interpreted as lane boundaries. In an example scenario, an AV could interpret a lane through an obstruction-free portion of a field or empty lot. In another example scenario, an AV could interpret a lane through a wide (e.g., wide enough for two or more lanes) road that does not have lane markings. In this scenario, the AV could communicate information about the lane to other AVs so that the other AVs can use the same lane information to coordinate path planning among themselves.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this description, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

As used herein, an AV system refers to the AV along with the array of hardware, software, stored data, and data generated in real-time that supports the operation of the AV. In an embodiment, the AV system is incorporated within the AV. In an embodiment, the AV system is spread across several locations.

In general, this document describes technologies applicable to any vehicles that have one or more autonomous capabilities including fully autonomous vehicles, highly autonomous vehicles, and conditionally autonomous vehicles, such as so-called Level 5, Level 4 and Level 3 vehicles, respectively (see SAE International's standard J3016: Taxonomy and Definitions for Terms Related to On-Road Motor Vehicle Automated Driving Systems, which is incorporated by reference in its entirety, for more details on the classification of levels of autonomy in vehicles). The technologies described in this document are also applicable to partially autonomous vehicles and driver assisted vehicles, such as so-called Level 2 and Level 1 vehicles (see SAE International's standard J3016: Taxonomy and Definitions for Terms Related to On-Road Motor Vehicle Automated Driving Systems). In an embodiment, one or more of the Level 1, 2, 3, 4 and 5 vehicle systems may automate certain vehicle operations (e.g., steering, braking, and using maps) under certain operating conditions based on processing of sensor inputs. The technologies described in this document can benefit vehicles in any levels, ranging from fully autonomous vehicles to human-operated vehicles.

Autonomous vehicles have advantages over vehicles that require a human driver. One advantage is safety. For example, in 2016, the United States experienced 6 million automobile accidents, 2.4 million injuries, 40,000 fatalities, and 13 million vehicles in crashes, estimated at a societal cost of $910+billion. U.S. traffic fatalities per 100 million miles traveled have been reduced from about six to about one from 1965 to 2015, in part due to additional safety measures deployed in vehicles. For example, an additional half second of warning that a crash is about to occur is believed to mitigate 60% of front-to-rear crashes. However, passive safety features (e.g., seat belts, airbags) have likely reached their limit in improving this number. Thus, active safety measures, such as automated control of a vehicle, are the likely next step in improving these statistics. Because human drivers are believed to be responsible for a critical pre-crash event in 95% of crashes, automated driving systems are likely to achieve better safety outcomes, e.g., by reliably recognizing and avoiding critical situations better than humans; making better decisions, obeying traffic laws, and predicting future events better than humans; and reliably controlling a vehicle better than a human.

Referring to FIG. 1, an AV system 120 operates the vehicle 100 along a trajectory 198 through an environment 190 to a destination 199 (sometimes referred to as a final location) while avoiding objects (e.g., natural obstructions 191, vehicles 193, pedestrians 192, cyclists, and other obstacles) and obeying rules of the road (e.g., rules of operation or driving preferences).

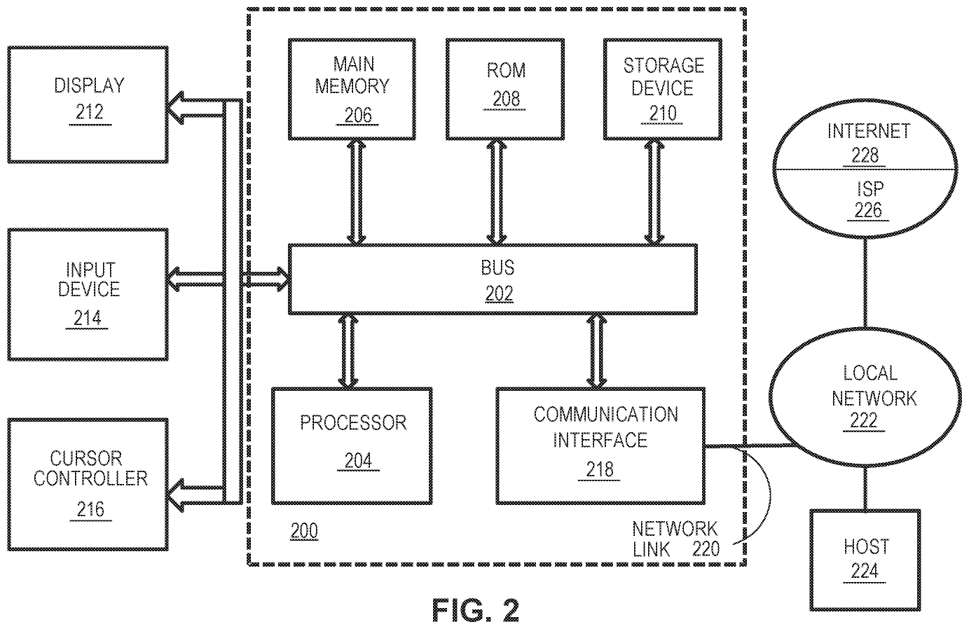

In an embodiment, the AV system 120 includes devices 101 that are instrumented to receive and act on operational commands from the computer processors 146. We use the term “operational command” to mean an executable instruction (or set of instructions) that causes a vehicle to perform an action (e.g., a driving maneuver). Operational commands can, without limitation, including instructions for a vehicle to start moving forward, stop moving forward, start moving backward, stop moving backward, accelerate, decelerate, perform a left turn, and perform a right turn. In an embodiment, computing processors 146 are similar to the processor 204 described below in reference to FIG. 2. Examples of devices 101 include a steering control 102, brakes 103, gears, accelerator pedal or other acceleration control mechanisms, windshield wipers, side-door locks, window controls, and turn-indicators.

In an embodiment, the AV system 120 includes sensors 121 for measuring or inferring properties of state or condition of the vehicle 100, such as the AV's position, linear and angular velocity and acceleration, and heading (e.g., an orientation of the leading end of vehicle 100). Example of sensors 121 are GPS, inertial measurement units (IMU) that measure both vehicle linear accelerations and angular rates, wheel speed sensors for measuring or estimating wheel slip ratios, wheel brake pressure or braking torque sensors, engine torque or wheel torque sensors, and steering angle and angular rate sensors.

In an embodiment, the sensors 121 also include sensors for sensing or measuring properties of the AV's environment. For example, monocular or stereo video cameras 122 in the visible light, infrared or thermal (or both) spectra, LiDAR 123, RADAR, ultrasonic sensors, time-of-flight (TOF) depth sensors, speed sensors, temperature sensors, humidity sensors, and precipitation sensors.

In an embodiment, the AV system 120 includes a data storage unit 142 and memory 144 for storing machine instructions associated with computer processors 146 or data collected by sensors 121. In an embodiment, the data storage unit 142 is similar to the ROM 208 or storage device 210 described below in relation to FIG. 2. In an embodiment, memory 144 is similar to the main memory 206 described below. In an embodiment, the data storage unit 142 and memory 144 store historical, real-time, and/or predictive information about the environment 190. In an embodiment, the stored information includes maps, driving performance, traffic congestion updates or weather conditions. In an embodiment, data relating to the environment 190 is transmitted to the vehicle 100 via a communications channel from a remotely located database 134.

In an embodiment, the AV system 120 includes communications devices 140 for communicating measured or inferred properties of other vehicles' states and conditions, such as positions, linear and angular velocities, linear and angular accelerations, and linear and angular headings to the vehicle 100. These devices include Vehicle-to-Vehicle (V2V) and Vehicle-to-Infrastructure (V2I) communication devices and devices for wireless communications over point-to-point or ad hoc networks or both. In an embodiment, the communications devices 140 communicate across the electromagnetic spectrum (including radio and optical communications) or other media (e.g., air and acoustic media). A combination of Vehicle-to-Vehicle (V2V) Vehicle-to-Infrastructure (V2I) communication (and, in some embodiments, one or more other types of communication) is sometimes referred to as Vehicle-to-Everything (V2X) communication. V2X communication typically conforms to one or more communications standards for communication with, between, and among autonomous vehicles.

In an embodiment, the communication devices 140 include communication interfaces. For example, wired, wireless, WiMAX, Wi-Fi, Bluetooth, satellite, cellular, optical, near field, infrared, or radio interfaces. The communication interfaces transmit data from a remotely located database 134 to AV system 120. In an embodiment, the remotely located database 134 also stores and transmits digital data (e.g., storing data such as road and street locations). Such data is stored on the memory 144 on the vehicle 100, or transmitted to the vehicle 100 via a communications channel from the remotely located database 134.

In an embodiment, the remotely located database 134 stores and transmits historical information about driving properties (e.g., speed and acceleration profiles) of vehicles that have previously traveled along trajectory 198 at similar times of day. In one implementation, such data can be stored on the memory 144 on the vehicle 100, or transmitted to the vehicle 100 via a communications channel from the remotely located database 134.

Computer processors 146 located on the vehicle 100 algorithmically generate control actions based on both real-time sensor data and prior information, allowing the AV system 120 to execute its autonomous driving capabilities.

In an embodiment, the AV system 120 includes computer peripherals 132 coupled to computer processors 146 for providing information and alerts to, and receiving input from, a user (e.g., an occupant or a remote user) of the vehicle 100. In an embodiment, peripherals 132 are similar to the display 212, input device 214, and cursor controller 216 discussed below in reference to FIG. 2. The coupling is wireless or wired. Any two or more of the interface devices can be integrated into a single device.

In an embodiment, the AV system 120 receives and enforces a privacy level of a passenger, e.g., specified by the passenger or stored in a profile associated with the passenger. The privacy level of the passenger determines how particular information associated with the passenger (e.g., passenger comfort data, biometric data, etc.) is permitted to be used, stored in the passenger profile, and/or stored on the cloud server 136 and associated with the passenger profile. In an embodiment, the privacy level specifies particular information associated with a passenger that is deleted once the ride is completed. In an embodiment, the privacy level specifies particular information associated with a passenger and identifies one or more entities that are authorized to access the information. Examples of specified entities that are authorized to access information can include other AVs, third party AV systems, or any entity that could potentially access the information.

A privacy level of a passenger can be specified at one or more levels of granularity. In an embodiment, a privacy level identifies specific information to be stored or shared. In an embodiment, the privacy level applies to all the information associated with the passenger such that the passenger can specify that none of her personal information is stored or shared. Specification of the entities that are permitted to access particular information can also be specified at various levels of granularity. Various sets of entities that are permitted to access particular information can include, for example, other AVs, cloud servers 136, specific third party AV systems, etc.

In an embodiment, the AV system 120 or the cloud server 136 determines if certain information associated with a passenger can be accessed by the AV 100 or another entity. For example, a third-party AV system that attempts to access passenger input related to a particular spatiotemporal location must obtain authorization, e.g., from the AV system 120 or the cloud server 136, to access the information associated with the passenger. For example, the AV system 120 uses the passenger's specified privacy level to determine whether the passenger input related to the spatiotemporal location can be presented to the third-party AV system, the AV 100, or to another AV. This enables the passenger's privacy level to specify which other entities are allowed to receive data about the passenger's actions or other data associated with the passenger.

FIG. 2 shows a computer system 200. In an implementation, the computer system 200 is a special purpose computing device. The special-purpose computing device is hard-wired to perform the techniques or includes digital electronic devices such as one or more application-specific integrated circuits (ASICs) or field programmable gate arrays (FPGAs) that are persistently programmed to perform the techniques, or can include one or more general purpose hardware processors programmed to perform the techniques pursuant to program instructions in firmware, memory, other storage, or a combination. Such special-purpose computing devices can also combine custom hard-wired logic, ASICs, or FPGAs with custom programming to accomplish the techniques. In various embodiments, the special-purpose computing devices are desktop computer systems, portable computer systems, handheld devices, network devices or any other device that incorporates hard-wired and/or program logic to implement the techniques.

In an embodiment, the computer system 200 includes a bus 202 or other communication mechanism for communicating information, and a processor 204 coupled with a bus 202 for processing information. The processor 204 is, for example, a general-purpose microprocessor. The computer system 200 also includes a main memory 206, such as a random-access memory (RAM) or other dynamic storage device, coupled to the bus 202 for storing information and instructions to be executed by processor 204. In one implementation, the main memory 206 is used for storing temporary variables or other intermediate information during execution of instructions to be executed by the processor 204. Such instructions, when stored in non-transitory storage media accessible to the processor 204, render the computer system 200 into a special-purpose machine that is customized to perform the operations specified in the instructions.

In an embodiment, the computer system 200 further includes a read only memory (ROM) 208 or other static storage device coupled to the bus 202 for storing static information and instructions for the processor 204. A storage device 210, such as a magnetic disk, optical disk, solid-state drive, or three-dimensional cross point memory is provided and coupled to the bus 202 for storing information and instructions.

In an embodiment, the computer system 200 is coupled via the bus 202 to a display 212, such as a cathode ray tube (CRT), a liquid crystal display (LCD), plasma display, light emitting diode (LED) display, or an organic light emitting diode (OLED) display for displaying information to a computer user. An input device 214, including alphanumeric and other keys, is coupled to bus 202 for communicating information and command selections to the processor 204. Another type of user input device is a cursor controller 216, such as a mouse, a trackball, a touch-enabled display, or cursor direction keys for communicating direction information and command selections to the processor 204 and for controlling cursor movement on the display 212. This input device typically has two degrees of freedom in two axes, a first axis (e.g., x-axis) and a second axis (e.g., y-axis), that allows the device to specify positions in a plane.

According to one embodiment, the techniques herein are performed by the computer system 200 in response to the processor 204 executing one or more sequences of one or more instructions contained in the main memory 206. Such instructions are read into the main memory 206 from another storage medium, such as the storage device 210. Execution of the sequences of instructions contained in the main memory 206 causes the processor 204 to perform the process steps described herein. In alternative embodiments, hard-wired circuitry is used in place of or in combination with software instructions.

The term “storage media” as used herein refers to any non-transitory media that store data and/or instructions that cause a machine to operate in a specific fashion. Such storage media includes non-volatile media and/or volatile media. Non-volatile media includes, for example, optical disks, magnetic disks, solid-state drives, or three-dimensional cross point memory, such as the storage device 210. Volatile media includes dynamic memory, such as the main memory 206. Common forms of storage media include, for example, a floppy disk, a flexible disk, hard disk, solid-state drive, magnetic tape, or any other magnetic data storage medium, a CD-ROM, any other optical data storage medium, any physical medium with patterns of holes, a RAM, a PROM, and EPROM, a FLASH-EPROM, NV-RAM, or any other memory chip or cartridge.

Storage media is distinct from but may be used in conjunction with transmission media. Transmission media participates in transferring information between storage media. For example, transmission media includes coaxial cables, copper wire and fiber optics, including the wires that comprise the bus 202. Transmission media can also take the form of acoustic or light waves, such as those generated during radio-wave and infrared data communications.

In an embodiment, various forms of media are involved in carrying one or more sequences of one or more instructions to the processor 204 for execution. For example, the instructions are initially carried on a magnetic disk or solid-state drive of a remote computer. The remote computer loads the instructions into its dynamic memory and send the instructions over one or more networks including wired or wireless networks. A modem local to the computer system 200 receives the data and appropriate circuitry places the data on the bus 202. The bus 202 carries the data to the main memory 206, from which processor 204 retrieves and executes the instructions. The instructions received by the main memory 206 can optionally be stored on the storage device 210 either before or after execution by processor 204.

The computer system 200 also includes a communication interface 218 coupled to the bus 202. The communication interface 218 provides a two-way data communication coupling to a network link 220 that is connected to a local network 222. For example, the communication interface 218 is a cellular modem, cable modem, or satellite modem. As another example, the communication interface 218 is a local area network (LAN) card to provide a data communication connection to a compatible LAN. In some implementations, wireless links are also implemented. In any such implementation, the communication interface 218 sends and receives electrical, electromagnetic, or optical signals that carry digital data streams representing various types of information.

The network link 220 typically provides data communication through one or more networks to other data devices. For example, the network link 220 provides a connection through the local network 222 to a host computer 224 or to a cloud data center or equipment operated by an Internet Service Provider (ISP) 226. The ISP 226 in turn provides data communication services through the world-wide packet data communication network now commonly referred to as the “Internet” 228. The local network 222 and Internet 228 both use electrical, electromagnetic or optical signals that carry digital data streams. The signals through the various networks and the signals on the network link 220 and through the communication interface 218, which carry the digital data to and from the computer system 200, are example forms of transmission media.

The computer system 200 sends messages and receives data, including program code, through the network(s), the network link 220, and the communication interface 218. In an embodiment, the computer system 200 receives code for processing. The received code is executed by the processor 204 as it is received, and/or stored in storage device 210, or other non-volatile storage for later execution.

### Autonomous Vehicle Architecture

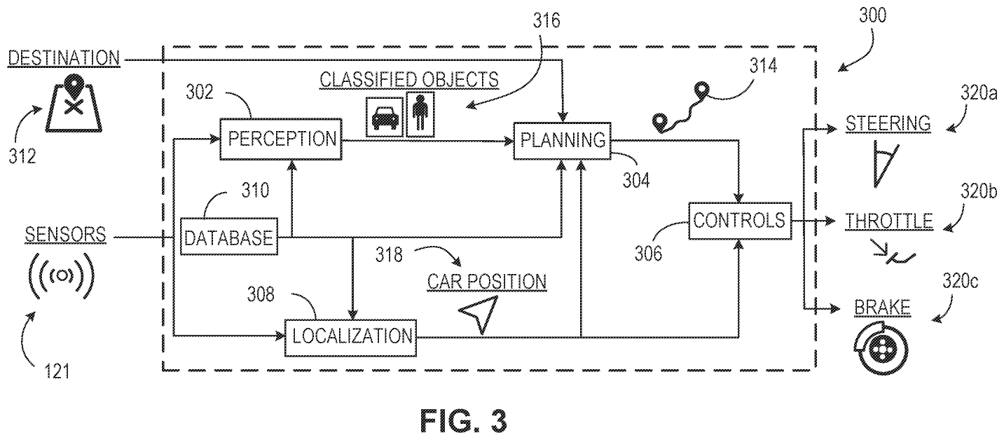

FIG. 3 shows an example architecture 300 for an autonomous vehicle (e.g., the vehicle 100 shown in FIG. 1). The architecture 300 includes a perception module 302 (sometimes referred to as a perception circuit), a planning module 304 (sometimes referred to as a planning circuit), a control module 306 (sometimes referred to as a control circuit), a localization module 308 (sometimes referred to as a localization circuit), and a database module 310 (sometimes referred to as a database circuit). Each module plays a role in the operation of the vehicle 100. Together, the modules 302, 304, 306, 308, and 310 can be part of the AV system 120 shown in FIG. 1. In some embodiments, any of the modules 302, 304, 306, 308, and 310 is a combination of computer software (e.g., executable code stored on a computer-readable medium) and computer hardware (e.g., one or more microprocessors, microcontrollers, application-specific integrated circuits (ASICs)), hardware memory devices, other types of integrated circuits, other types of computer hardware, or a combination of any or all of these things). Each of the modules 302, 304, 306, 308, and 310 is sometimes referred to as a processing circuit (e.g., computer hardware, computer software, or a combination of the two). A combination of any or all of the modules 302, 304, 306, 308, and 310 is also an example of a processing circuit.

In use, the planning module 304 receives data representing a destination 312 and determines data representing a trajectory 314 (sometimes referred to as a route) that can be traveled by the vehicle 100 to reach (e.g., arrive at) the destination 312. In order for the planning module 304 to determine the data representing the trajectory 314, the planning module 304 receives data from the perception module 302, the localization module 308, and the database module 310.

The perception module 302 identifies nearby physical objects using one or more sensors 121, e.g., as also shown in FIG. 1. The objects are classified (e.g., grouped into types such as pedestrian, bicycle, automobile, traffic sign, etc.) and a scene description including the classified objects 316 is provided to the planning module 304.

The planning module 304 also receives data representing the AV position 318 from the localization module 308. The localization module 308 determines the AV position by using data from the sensors 121 and data from the database module 310 (e.g., a geographic data) to calculate a position. For example, the localization module 308 uses data from a GNSS (Global Navigation Satellite System) sensor and geographic data to calculate a longitude and latitude of the AV. In an embodiment, data used by the localization module 308 includes high-precision maps of the roadway geometric properties, maps describing road network connectivity properties, maps describing roadway physical properties (such as traffic speed, traffic volume, the number of vehicular and cyclist traffic lanes, lane width, lane traffic directions, or lane marker types and locations, or combinations of them), and maps describing the spatial locations of road features such as crosswalks, traffic signs or other travel signals of various types. In an embodiment, the high-precision maps are constructed by adding data through automatic or manual annotation to low-precision maps.

The control module 306 receives the data representing the trajectory 314 and the data representing the AV position 318 and operates the control functions 320a-c (e.g., steering, throttling, braking, ignition) of the AV in a manner that will cause the vehicle 100 to travel the trajectory 314 to the destination 312. For example, if the trajectory 314 includes a left turn, the control module 306 will operate the control functions 320a-c in a manner such that the steering angle of the steering function will cause the vehicle 100 to turn left and the throttling and braking will cause the vehicle 100 to pause and wait for passing pedestrians or vehicles before the turn is made.

### Autonomous Vehicle Inputs

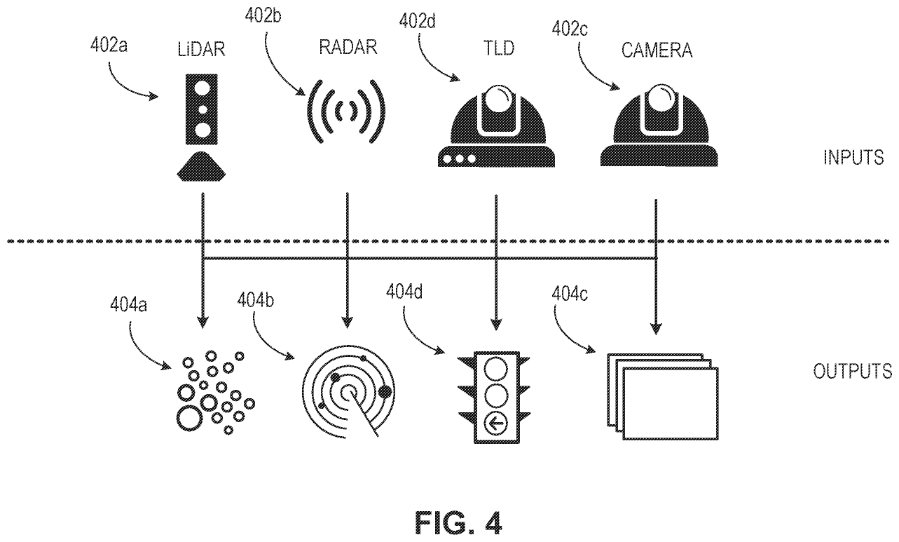

FIG. 4 shows an example of inputs 402a-d (e.g., sensors 121 shown in FIG. 1) and outputs 404a-d (e.g., sensor data) that is used by the perception module 302 (FIG. 3). One input 402a is a LiDAR (Light Detection and Ranging) system (e.g., LiDAR 123 shown in FIG. 1). LiDAR is a technology that uses laser light (e.g., bursts of light such as infrared light or light at other optical waveforms) to obtain data about physical objects in its line of sight. A LiDAR system produces LiDAR data as output 404a. For example, LiDAR data is collections of 3D or 2D points (also known as a point clouds) that are used to construct a representation of the environment 190.

Another input 402b is a radar system. Radar technology uses radio waves to obtain data about nearby physical objects. Radars can obtain data about objects not within the line of sight of a LiDAR system. A radar system produces RADAR data as output 404b. For example, radar data are one or more radio frequency electromagnetic signals that are used to construct a representation of the environment 190.

Another input 402c is a camera system. A camera system uses one or more cameras (e.g., digital cameras using a light sensor such as a charge-coupled device (CCD)) to obtain information about nearby physical objects. A camera system produces camera data as output 404c. Camera data often takes the form of image data (e.g., data in an image data format such as RAW, JPEG, PNG, etc.). In some examples, the camera system has multiple independent cameras, e.g., for the purpose of stereopsis (stereo vision), which enables the camera system to perceive depth. Although the objects perceived by the camera system are described here as “nearby,” this is relative to the AV. In some embodiments, the camera system is configured to “see” objects far, e.g., up to a kilometer or more ahead of the AV. Accordingly, in some embodiments, the camera system has features such as sensors and lenses that are optimized for perceiving objects that are far away.

Another input 402d is a traffic light detection (TLD) system. A TLD system uses one or more cameras to obtain information about traffic lights, street signs, and other physical objects that provide visual navigation information. A TLD system produces TLD data as output 404d. TLD data often takes the form of image data (e.g., data in an image data format such as RAW, JPEG, PNG, etc.).

In some embodiments, outputs 404a-d are combined using a sensor fusion technique. Thus, either the individual outputs 404a-d are provided to other systems of the vehicle 100 (e.g., provided to a planning module 304 as shown in FIG. 3), or the combined output can be provided to the other systems, either in the form of a single combined output or multiple combined outputs of the same type (e.g., using the same combination technique or combining the same outputs or both) or different types type (e.g., using different respective combination techniques or combining different respective outputs or both). In some embodiments, an early fusion technique is used. An early fusion technique is characterized by combining outputs before one or more data processing steps are applied to the combined output. In some embodiments, a late fusion technique is used. A late fusion technique is characterized by combining outputs after one or more data processing steps are applied to the individual outputs.

### Event Detection Mechanisms

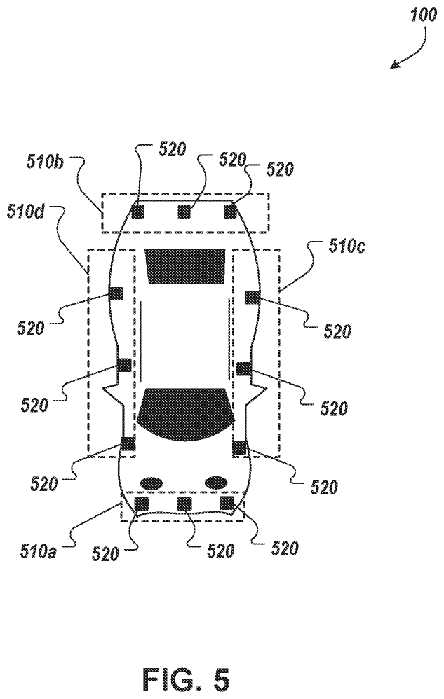

FIG. 5 shows an example of sensors 520 distributed about body regions 510a-d of the vehicle 100. The body of the vehicle 100, e.g., vehicle body, can be divided into different body regions. In this example, four body regions 510a-d are shown. Other or different divisions are possible. While FIG. 5 shows the regions 510a-d as being non-contiguous, a body region can be contiguous with one or more other body regions. The regions 510a-d can include a body region 510a associated with the front bumper, a body region 510b associated with the rear bumper, a body region 510c associated with the driver's side, and a body region 510d associated with the passenger's side of the vehicle 100. The top (or portion thereof) of the vehicle 100 can also be a body region.

The vehicle 100 can include sensors 520 that are distributed about the vehicle 100. One or more of the sensors 520 can be configured to detect vibration, sound, or both. A body region 510a-d can include one or more different types of sensors 520. Various types of sensors 520 include audio, piezoelectric, or MEMS. Other types of sensors are possible. For example, the sensors 520 can include piezoelectric sensors such as piezoelectric disc sensors, array of piezoelectric sensors, a cable of piezoelectric sensors, or a film containing at least one piezoelectric sensor. A piezoelectric cable, for example, can be placed inside a front lip of a bumper. Piezoelectric elements, for example, can be placed below a bumper on rubber antennae, which can form a curtain of rubber antennae. The sensors 520 can include audio sensors such as microphones. The sensors 520 can include one or more MEMS gyroscope sensors. In some embodiments, sensors 520 such as MEMS accelerometers can be placed on or about tires or suspension. The sensors 520 can be used for event detection such as collision detection. In addition to collision detection, the outputs of the sensors 520 can be used by other systems such as a perception module 302, a planning module 304, or a control module 306.

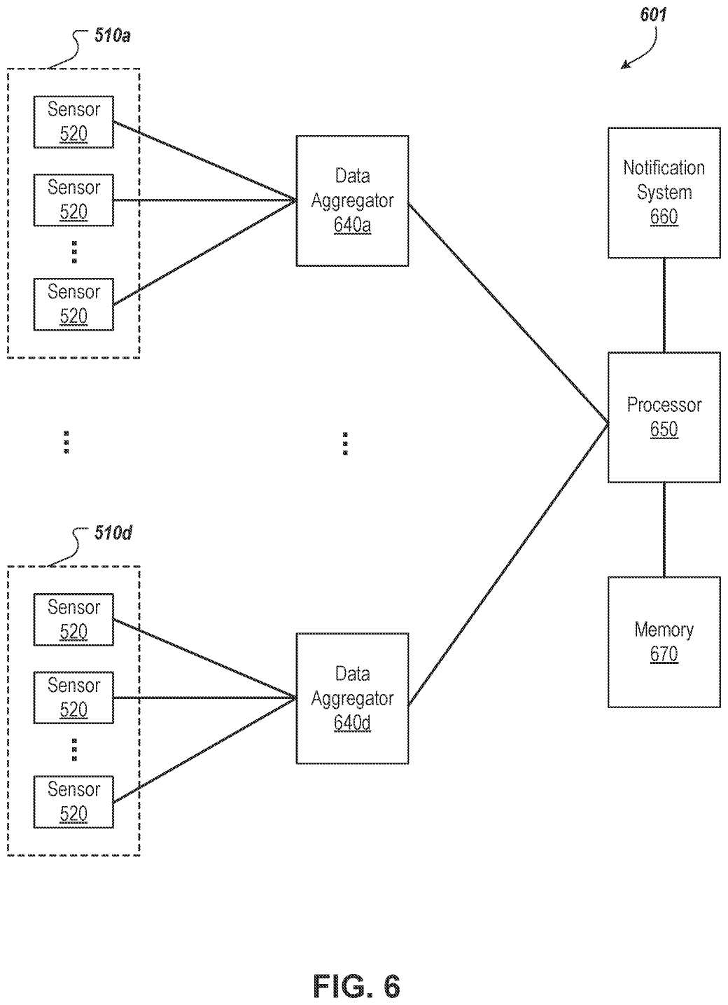

FIG. 6 shows an example of an architecture of a distributed sensor system 601. The outputs of sensors 520, which are associated with body regions 510a-d, can be provided to a processor 650 for analysis. The processor 650 can include one or more ASICs, FPGAs, processors, or a combination thereof. The sensors 520 can be grouped by body region 510a-d. For example, sensors 520 associated with the front bumper body region 510a can form a group, whereas sensors 520 associated with the passenger-side body region 510d can form a different group. In some embodiments, data from a sensor 520 can include a sensor identifier, a body region identifier, and a sensor measurement.

In some embodiments, each of the body regions 510a-d are associated with a corresponding data aggregator 640a-d, which aggregates the outputs for all sensors in a region and produces an aggregated sensor feed for the region to the processor 650. For example, a data aggregator 640a can take voltage measurements of analog sensor outputs from different sensors 520 in a body region 510a, and generate a sensor data stream that includes sensor records containing voltage measurements, sensor identifiers, body region identifiers, timestamps, or a combination thereof.

Connections among the sensors 520 and the data aggregators 640a-d can be analog connections, digital connections, or a combination thereof. Connections among the data aggregators 640a-d and the processor 650 can be digital connections. Various examples of digital connections include Peripheral Sensor Interface (PSIS), Serial Peripheral Interface (SPI), or inter-integrated circuit (I2C) bus. Other examples of digital connections are possible.

In some embodiments, the memory 670 can store sensor measurements values. In some embodiments, the memory 670 stores instructions that, when executed by the processor 650, can cause the processor 670 to perform operations which can include obtaining data associated with a sensor measurement from at least one sensor 520. The operations can include determining that the at least one sensor measurement from a sensor 520 in a body region 510a-d is associated with a specific region event type, e.g., a contact event type associated with a specific one of the body regions 510a-d. The operations can include determining that an event associated with the specific region event type occurred based on determining that the at least one sensor measurement is associated with the specific region event type and that the body region responsible for sourcing the sensor measurement is associated with the specific region event type.

Sensor data from the sensors 520 can be used to isolate a specific one of the body regions 510a-d that is associated with a contact event. For example, the body region 510d associated with the passenger's side of the vehicle 100 may come into contact with a pedestrian. Sensors within that body region 510d (passenger-side door) may produce one or more signal patterns, and the processor 650 can determine that the signal patterns originated from that body region 510d and determine that the contact event is a passenger-side door contact event.

If an event has been detected, by the processor 650, then the processor 650 can cause the notification system 660 to generate a notification such as an visual or audible notification. In some embodiments, the notification includes a location of a body region associated with the event. In some embodiments, the notification can be displayed on a vehicle's head-up display in the vehicle. In some embodiments, the notification can be displayed on a vehicle's head-down display in the vehicle.

In some embodiments, the processor 650 can be configured to obtain sensor measurements from the sensors 520, and detect a collision event of a first type of collision events (e.g., low impact) based on the sensor measurements, where the first type of collision events is less severe than a second type of collision events (e.g., high impact). Low impact collision events may be referred to as contact events. The processor 650 can be configured to detect the collision event based on a determination of whether a mechanical shock, vibration, or noise that is sensed by at least a portion of the sensors 520 is localized to a particular body region of the body regions 510a-d. The processor 650 can fuse sensor data from multiple sensors 520 to filter out, e.g., exclude, sensor measurements that are not likely to be a body region event. For example, if accelerometers in multiple regions 510a-d produce a similar pattern at or around the same time, then the processor 650 may trigger a high-impact notification rather than a localized body region contact event.

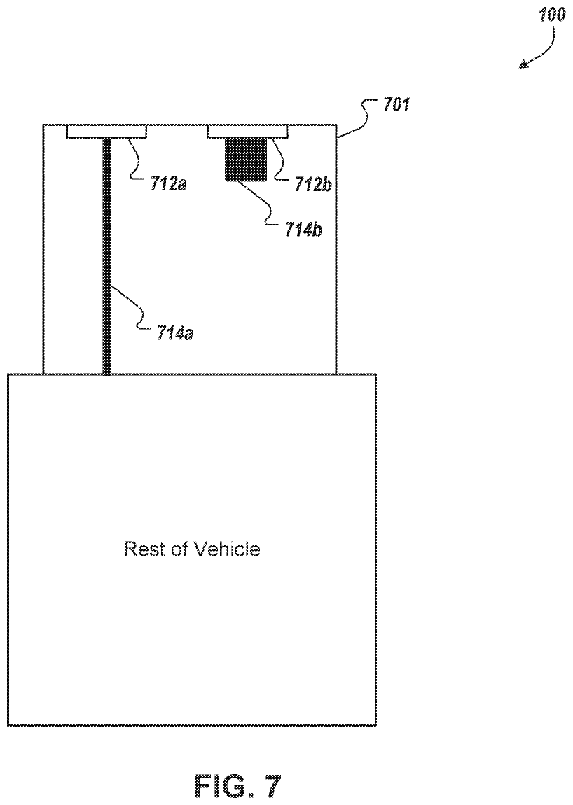

FIG. 7 shows a diagram of an example of sensor configurations within a body region 701 of the vehicle 100. The body region 701 can be a front or rear bumper, but other body regions are possible. The body region 701 can be equipped with one or more sensors such as piezoelectric disc sensors 712a-b. The piezoelectric disc sensors 712a-b can detect distortions of the surface of a body region, such as those caused by coming into contact with an external source.

A first sensor configuration includes a piezoelectric disc sensor 712a attached to an interior side of the body region 701 (e.g., interior side of a bumper) that is closed to the outside of the vehicle 100. A rod 714a can be connected between the piezoelectric disc sensor 712a and an interior side of the body region 701 that is closest to the rest of the vehicle 100. In an embodiment, the rod 714a can be a rigid mechanical connection mechanical connection to the rest of the vehicle 100. In an embodiment, the rod 714a can be a compressible mechanical connection to the rest of the vehicle 100, which can be less compressible than the original bumper filling.

A second sensor configuration includes a piezoelectric disc sensor 712b attached to an interior side of the body region 701 (e.g., interior side of a bumper). A weight 714b can be attached to the piezoelectric disc sensor 712b to amplify vibrations.

In some embodiments, a film of piezoelectric crystals or multiple patches of this film can be attached to the interior or exterior side of the body region 701. In some embodiments, a protective film can be placed over the piezoelectric layer to protect piezoelectric sensor(s).

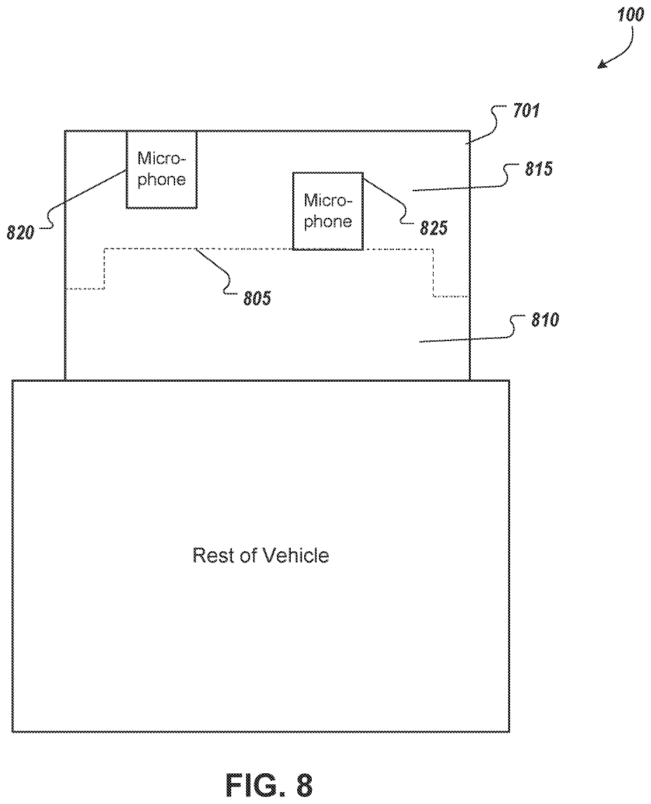

FIG. 8 shows a diagram of an example of audio sensors, e.g., microphones 820, 825, within a body region 701 of the vehicle 100. The body region 701 can be a front or rear bumper, but other body regions are possible. The body region 701 can include a cavity 815. In this example, a boundary line 805 is shown to denote the interior boundary of the cavity 815. As shown, there is a space 810 between the boundary line 805 (and accordingly the cavity 815) and the rest of the vehicle 100.

The audio sensors, e.g., microphones 820, 825, can be located inside of the cavity 815. The cavity 815 can act as a sound box. Audio data from the microphones 820, 825 can be used to detect events including collision events which can include body region events. The difference in timing between audio signals from the respective microphones 820, 825 can be used for locating a direction of an audible event. In this example, microphone 820 is closer to the outside of the vehicle 100, whereas microphone 825 is farther from the outside of the vehicle 100 (and closer to the rest of the vehicle 100).

If the direction of the audible event is from outside the vehicle 100 (e.g., signal pattern was observed at microphone 820 and then later at microphone 825), the audible event can be further processed for the purposes of collision detection. If the direction of the audible event is from an engine compartment (e.g., signal pattern was observed at microphone 825 and then later at microphone 820), the audible event can be disregarded for the purposes of collision detection. A processor can filter audio sensor data from the microphones 820, 825. Such filtering can include determining an origin of a noise based on sensor data from the microphones 820, 825 and preventing further processing of audio sensor data that are deemed to originate from within the vehicle.

In some embodiments, the microphones 820, 825 can include an omnidirectional microphone 820 and a directional microphone 825. A processor can filter sensor data from the directional microphone 820 based on sensor data from the omnidirectional microphone 820. For example, such filtering can remove ambient noises such as engine noise from the directional microphone 820.

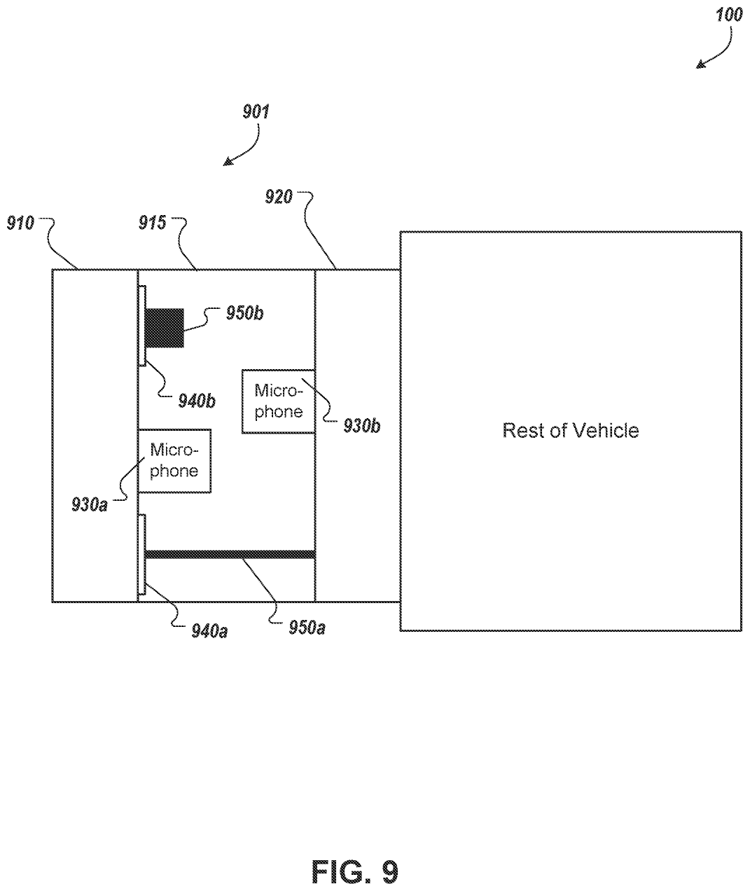

FIG. 9 shows a diagram of an example of sensors within a door region 901 of the vehicle 100. The door region 901 can include an external door cover 910, cavity 915, and internal door cover 920. The cavity 915 can include one or more sensors such as microphones 930a-b and piezoelectric disc sensors 940a-b. Other types and quantities of sensors are possible. For example, in some embodiments, a cavity 915 may have a single microphone. In some embodiments, a vehicle can have multiple door regions on the same side of the vehicle 100.

Audio sensors, e.g., microphones 930a-b, can be located inside the cavity 915. In this example, microphone 930a is located on a side of the cavity 915 that is adjacent to the external door cover 910, whereas microphone 930b is located on a side of the cavity 915 that is adjacent to the internal door cover 920. In some embodiments, door region 901 can include sound insulation between the internal door cover 920 and the cavity 915 to reduce sound coming from inside the vehicle cabin.

Audio data from the microphones 930a-b can be used to detect events including collision events. The difference in timing between audio signals from the respective microphones 930a-b can be used for locating a direction of an audible event. In this example, microphone 930a is closer to the outside of the vehicle 100, whereas microphone 930b is farther from the outside of the vehicle 100. If the direction of the audible event is from outside of the vehicle (e.g., signal pattern was observed at microphone 930a and then later at microphone 930b), the audible event can be further processed for the purposes of collision detection. If the direction of the audible event is from the interior of the vehicle 100 due to a passenger's kick or other activity (e.g., signal pattern was observed at microphone 930b and then later at microphone 930a), the audible event can be disregarded for the purposes of collision detection.

A first piezoelectric disc sensor 940a can be attached to a side of the cavity 915 that is adjacent to the external door cover 910. A rod 950a can be connected between the first piezoelectric disc sensor 940a and a side of the cavity 915 that is adjacent to the internal door cover 920. In an embodiment, the rod 950a can be a rigid mechanical connection mechanical connection to the rest of the vehicle 100. In an embodiment, the rod 950a can be a compressible mechanical connection to the rest of the vehicle 100. A second piezoelectric disc sensor 940b can be attached to a side of the cavity 915 that is adjacent to the external door cover 910. A weight 950b can be attached to the second piezoelectric disc sensor 940b to amplify vibrations.

A processor can obtain sensor data from the sensors including microphones 930a-b, piezoelectric disc sensors 940a-b, or a combination thereof. The processor can fuse data from the sensors. For example, an array of sensors or multiple arrays can provide detailed information on a location of an event after data fusion. In some embodiments, a body region event can be generated if both data from the microphones 930a-b and data from the piezoelectric disc sensors 940a-b indicate that the event occurred.

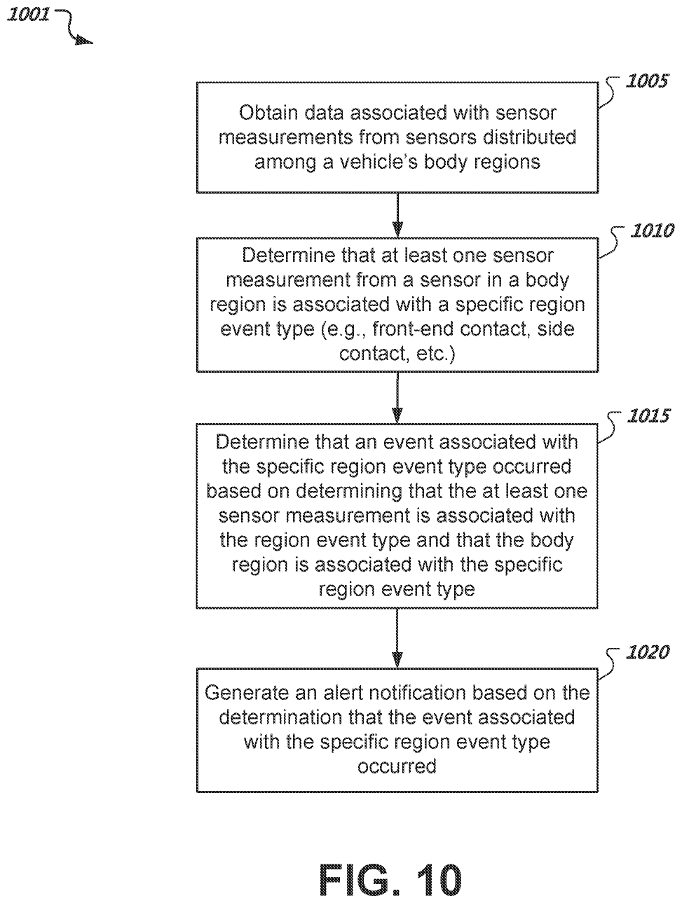

FIG. 10 shows a flowchart of an example of a process 1001 that performs event detection. The process 1001 can be performed by a processor such as processors 146 of FIG. 1 or processor 650 of FIG. 6. At 1005, the process 1001 can include obtaining data associated with sensor measurements from sensors distributed among a vehicle's body regions. Obtaining a measurement can include receiving a sensor event from a sensor, polling a sensor for sensor data, or monitoring voltage on a line coupled with the sensor. Other technique for obtaining sensor measurements are possible.

At 1010, the process 1001 can include determining that at least one sensor measurement from a sensor in a body region is associated with a specific region event type. A specific region event type can be an event type associated with a body region, e.g., front-end contact event type, side contact event type, etc. Determining that the at least one sensor measurement from the sensor in the body region is associated with the specific region event type can include determining that the at least one sensor measurement from the sensor in the body region corresponds to or corresponds to a range representing the event type. Determining that the at least one sensor measurement from the sensor in the body region is associated with the specific region event type can include accessing a sensor record containing a body region identifier and a sensor measurement, and using the body region identifier to determine a body region event type. Determining that at least one sensor measurement from a sensor in a body region is associated with a specific region event type can include analyzing sensor measurements from multiple body regions.

In some embodiments, an event may be sensed by sensors in two or more adjacent body regions. In some embodiments, a specific region event type can be an event type associated with a body region whose sensors predominately sensed an event, e.g., body region A is associated with 75% of the sensor measurements within a measurement window (with non-predominate body regions B and C making up the remaining measurements). Other percentages are possible such as a percentage greater than 50%.

At 1015, the process 1001 can include determining that an event associated with the specific region event type occurred based on determining that the at least one sensor measurement is associated with the region event type and that the body region is associated with the specific region event type. In some embodiments, if a single body region or multiple neighboring body regions are affected by a specific source such as a mechanical shock, vibration, or noise source, then a collision, such as a low-severity collision, is likely to have taken place. In some embodiments, determining that an event associated with the specific region event type occurred can include analyzing sensor measurements from multiple adjacent body regions. In some embodiments, determining that an event associated with the specific region event type occurred can include excluding sensor measurements associated with a mechanical shock, vibration, or noise event that is sensed by sensors in two or more body regions. Note that while the process 1001 may exclude such sensor measurement another process may use them for other purposes. In some embodiments, data from multiple sensors can be used to locate a position and direction of an impact.

At 1020, the process 1001 can include generating an alert notification based on the determination that the event associated with the specific region event type occurred. In some embodiments, the alert notification can be displayed on a heads-up display in the vehicle, e.g., a portion of a vehicle outline corresponding to the body region where a contact event occurred may be highlighted.

In some embodiments, a vehicle includes a vehicle body containing body regions, sensors, processor, and memory. The sensors can include at least one sensor positioned about at least one body region of the body regions. The body regions can include a front bumper, a rear bumper, a driver-side door, and a passenger-side door. The at least one body region can be associated with a specific region event type. Different body regions can be associated with different body region event types.

The sensors can include piezoelectric sensors such as piezoelectric disc sensors, array of piezoelectric sensors, a cable of piezoelectric sensors, or a film containing at least one piezoelectric sensor. The sensors can include audio sensors such as microphones. The sensors can include MEMS gyroscope sensors. Data aggregators can be used to aggregate data. Data aggregators can be respectively associated with the vehicle's body regions. A data aggregator of a respective body region can be configured to aggregate sensor data for sensors associated with the respective body region.

The memory can store instructions thereon that, when executed by the processor, cause the processor to perform operations. The operations can include obtaining data associated with at least one sensor measurement from the at least one sensor. The operations can include determining that the at least one sensor measurement is associated with the region event type. The operations can include determining that an event associated with the region event type occurred based on determining that the at least one sensor measurement is associated with the region event type and that the at least one body region is associated with the region event type. In some embodiments, the operations include generating an alert notification based on a determination that the event associated with the region event type occurred.

Determining that the event associated with the region event type occurred can include determining whether a mechanical shock, vibration, or noise that is sensed by at least a portion of the plurality of sensors is localized to a particular body region of the plurality of body regions. The operations can include detecting a mechanical shock, vibration, or noise event that is sensed by sensors in two or more body regions of the plurality of body regions; and detecting the region event type by excluding sensor measurements associated with a mechanical shock, vibration, or noise event that is sensed by sensors in two or more body regions of the plurality of body regions.

Sensor data can include audio data. In some embodiments, the sensors includes a microphone. Determining that the event associated with the region event type occurred can include using one or more sensor measurements associated with the microphone. Sensor measurements associated with the microphone can be analyzed by a processor to detect collision-related sounds.

In some embodiments, the sensors includes a first microphone and a second microphone that are arranged in the same body region. In some embodiments, the operations can include filtering sensor data from the first microphone based on sensor data from the second microphone. In some embodiments, the operations can include determining an origin of a noise based on sensor data from the first microphone and sensor data from the second microphone. Determining that the event associated with the region event type occurred can include determining that the noise originated from outside of a vehicle.

A non-transitory computer-readable storage medium can include one or more programs for execution by one or more processors of a device. The one or more programs can include instructions which, when executed by the one or more processors, cause the device to perform a method described herein, such as process 1001 of FIG. 10.

In the foregoing description, embodiments of the inventions have been described with reference to numerous specific details that may vary from implementation to implementation. The description and drawings are, accordingly, to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims. In addition, when we use the term “further comprising,” in the foregoing description or following claims, what follows this phrase can be an additional step or entity, or a sub-step/sub-entity of a previously-recited step or entity.

1. A system comprising:
a vehicle body comprising a plurality of body regions;
a plurality of sensors comprising at least one sensor positioned about at least one body region of the plurality of body regions, the at least one body region associated with a region event type;
at least one processor; and
at least one memory storing instructions thereon that, when executed by the at least one processor, cause the at least one processor to perform operations comprising:
obtaining data associated with at least one sensor measurement from the at least one sensor,
determining that the at least one sensor measurement is associated with the region event type, and
determining that an event associated with the region event type occurred based on determining that the at least one sensor measurement is associated with the region event type and that the at least one body region is associated with the region event type.

2. The system of claim 1, wherein the plurality of body regions comprises a front bumper, a rear bumper, a driver-side door, and a passenger-side door.

3. The system of claim 1, wherein the operations comprise generating an alert notification based on a determination that the event associated with the region event type occurred.

4. The system of claim 1, wherein determining that the event associated with the region event type occurred comprises determining whether a mechanical shock, vibration, or noise that is sensed by at least a portion of the plurality of sensors is localized to a particular body region of the plurality of body regions.

5. The system of claim 1, wherein the operations comprise detecting a mechanical shock, vibration, or noise event that is sensed by sensors in two or more body regions of the plurality of body regions, and wherein determining that the event associated with the region event type occurred comprises excluding sensor measurements associated with a mechanical shock, vibration, or noise event that is sensed by sensors in two or more body regions of the plurality of body regions.

6. The system of claim 1, comprising:
a plurality of data aggregators that are respectively associated with the plurality of body regions, wherein each data aggregator of a respective body region is configured to aggregate sensor data for sensors associated with the respective body region.

7. The system of claim 1, wherein the plurality of sensors comprises at least one piezoelectric sensor or micro-electro-mechanical systems (MEMS) gyroscope sensor.

8. The system of claim 1, wherein the plurality of sensors includes a microphone, and wherein determining that the event associated with the region event type occurred comprises using one or more sensor measurements associated with the microphone.

9. The system of claim 1, wherein the plurality of sensors includes a first microphone and a second microphone that are arranged in the same body region, and wherein the operations comprise determining an origin of a noise based on sensor data from the first microphone and sensor data from the second microphone, and wherein determining that the event associated with the region event type occurred comprises determining that the noise originated from outside of the vehicle body.

10. A system comprising:
at least one processor; and
at least one memory storing instructions thereon that, when executed by the at least one processor, cause the at least one processor to perform operations comprising:
obtaining data associated with at least one sensor measurement from at least one sensor of a plurality of sensors associated with a vehicle body, the at least one sensor positioned about at least one body region of a plurality of body regions of the vehicle body,
determining that the at least one sensor measurement is associated with a region event type, and
determining that an event associated with the region event type occurred based on determining that the at least one sensor measurement is associated with the region event type and that the at least one body region is associated with the region event type.

11. The system of claim 10, wherein the plurality of body regions comprises a front bumper, a rear bumper, a driver-side door, and a passenger-side door.

12. The system of claim 10, wherein the operations comprise generating an alert notification based on a determination that the event associated with the region event type occurred.

13. The system of claim 10, wherein determining that the event associated with the region event type occurred comprises determining whether a mechanical shock, vibration, or noise that is sensed by at least a portion of the plurality of sensors is localized to a particular body region of the plurality of body regions.

14. The system of claim 10, wherein the operations comprise detecting a mechanical shock, vibration, or noise event that is sensed by sensors in two or more body regions of the plurality of body regions, and wherein determining that the event associated with the region event type occurred comprises excluding sensor measurements associated with a mechanical shock, vibration, or noise event that is sensed by sensors in two or more body regions of the plurality of body regions.

15. The system of claim 10, wherein the plurality of sensors comprises at least one piezoelectric sensor or micro-electro-mechanical systems (MEMS) gyroscope sensor.

16. The system of claim 10, wherein the plurality of sensors includes a microphone, and wherein determining that the event associated with the region event type occurred comprises using one or more sensor measurements associated with the microphone.

17. The system of claim 10, wherein the plurality of sensors includes a first microphone and a second microphone that are arranged in the same body region, and wherein the operations comprise determining an origin of a noise based on sensor data from the first microphone and sensor data from the second microphone, and wherein determining that the event associated with the region event type occurred comprises determining that the noise originated from outside of the vehicle body.

18. A method comprising:
obtaining data associated with at least one sensor measurement from at least one sensor of a plurality of sensors associated with a vehicle body, the at least one sensor positioned about at least one body region of a plurality of body regions of the vehicle body;
determining that the at least one sensor measurement is associated with a region event type;
determining that an event associated with the region event type occurred based on determining that the at least one sensor measurement is associated with the region event type and that the at least one body region is associated with the region event type; and
generating an alert notification based on a determination that the event associated with the region event type occurred.

19. The method of claim 18, comprising:
detecting a mechanical shock, vibration, or noise event that is sensed by sensors in two or more body regions of the plurality of body regions, wherein determining that the event associated with the region event type occurred comprises excluding sensor measurements associated with a mechanical shock, vibration, or noise event that is sensed by sensors in two or more body regions of the plurality of body regions.

20. A non-transitory computer-readable storage medium comprising at least one program for execution by at least one processor of a device, the at least one program including instructions which, when executed by the at least one processor, cause the device to perform the method of claim 18.
